(19) United States
(12) Patent Application Publication
(10) Pub. No.: US 2009/0284939 A1
(43) Pub. Date: Nov. 19, 2009

(54) Alignment plate

(75) Inventor: Mitsuo Suehiro, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 12/458,694

(22) Filed: Jul. 21, 2009

Related U.S. Application Data
(62) Division of application No. 11/641,747, filed on Dec. 20, 2006.

(30) Foreign Application Priority Data
Jan. 19, 2006 (JP) 2006-011658

(51) Int. Cl. H05K 1/18

(52) U.S. Cl. 361/760

(57) ABSTRACT

A mounting material alignment plate of the present invention is operative to allow an electronic component to be mounted on a printed circuit board and has a plurality of bores that admit terminals of the electronic component to be placed. The mounting material alignment plate has dents formed on one surface, on which the electronic component is located, around the individual bores, and recesses formed on another surface opposite to the one surface on which the electronic component is located.

### BACKGROUND OF THE INVENTION

1. Field of the Invention

The present invention relates to mounting component parts of printed substrates.

2. Description of the Related Art

In the related art, attempts have heretofore been made for mounting an electronic component onto a printed circuit board in mounting techniques listed below.

FIGS. 1A to 1C are views showing the related art technology of mounting an electronic component onto a printed circuit board.

FIGS. 1A to 1C are cross-sectional views of the electronic component 1 and the printed circuit board 6.

In FIG. 1A, an electronic component 1 has lead terminals 2, 3 to which solder rings 4, 5 are press fitted in respective fixed places. In addition, as shown in FIG. 1B, the electronic component 1 is placed on the printed circuit board 6. When this takes place, the lead terminals 2, 3 of the electronic component 1 are inserted to through-holes 7, 8 formed in the printed circuit board 6. As shown in FIG. 1C, as reflow treatment is conducted after the electronic component 1 has been placed on the printed circuit board 6, the solder rings 4, 5 are caused to melt and filled in the through-holes 7, 8, to which the lead terminals 2, 3 are inserted and the electronic component 1 is mounted on the printed circuit board 6. In general, the amount of solder is equivalent to the amount of solder formed in fillets on upper and lower areas of the through-holes 7, 8. Also, the through-holes 7, 8 have surfaces formed with lands 9, 10, respectively, which are generally made of copper.

FIG. 2 is a cross-sectional view of the lead terminal 2 and the solder ring 4.

As shown in FIG. 2, the solder ring is formed in a cylindrical shape and the lead terminal is formed in a rectangular solid. Further, a cross sectional area of the lead terminal 2 has a diagonal line that is longer in structure than an inner diameter of the solder ring 4. This allows the solder ring 4 to be fixedly secured to the lead terminal 2 when the lead terminal 2 is press fitted to the solder ring 4.

With the mounting technique illustrated in FIGS. 1A to 1C, due to the solder rings 4, 5 adapted to be directly mounted to the lead terminals 2, 3 upon press fitting, the solder rings 4, 5 need to be formed in shapes in conformity to shapes such as angular pins or rounds pins of the lead terminals 2, 3 and, thus, the mounting of the electronic component cannot be efficiently performed.

Japanese Patent Application Laid-Open No. 7-32042 and Japanese Patent Application Laid-Open No. 5-13649 relates to technique of mounting an electronic component using a through-hole.

FIGS. 3A and 3B are views showing the related art, disclosed in Patent Publication Literature 1, wherein an electronic component is mounted on a printed circuit board using a bracket.

FIG. 3A is a view showing a status under which the electronic component 31 is mounted on the bracket 40.

In mounting the electronic component 31 onto the printed circuit board (not shown), the electronic component 31 is first placed on the bracket 40. The bracket 40 has bores 38, 39 formed at positions in alignment with positions of lead terminals 32, 33 of the electronic component 31 to be placed. Also, the bracket 40 has one surface, on a side on which the electronic component 31 is placed, formed with dents, referred to as counterbores 36, 37, in areas around the individual bores 38, 39. Solder rings 34, 35 are placed into the counterbores 36, 37, respectively.

As shown in FIG. 3B, the electronic component 31 is placed on the bracket 40. The bracket 40 takes a structure such that the lead terminals 32, 33 are inserted to the bores 38, 39 so as to penetrate through the bracket 40. Ends of the lead terminals 32, 33 protruding from the bracket 40 are further inserted to through-holes of the printed circuit board. Then, as reflow treatment is conducted, the solder rings 36, 37 are caused to melt to allow the through-holes to be filled with solder whereby the electronic component 31 is mounted on the printed circuit board. Here, the printed circuit board is not illustrated in FIGS. 3A and 3B.

FIGS. 4A and 4B are views showing the related art wherein lead terminals inserted to through-holes are soldered in DIP flow. FIG. 4A is a view wherein an electronic component 41 is soldered to a printed circuit board and FIG. 4B is a view wherein the operation for soldering the electronic component 41 to the printed circuit board has been completed.

FIGS. 4A and 4B are cross-sectional views showing the electronic component 41, the printed circuit board 44 and the DIP flow 47.

When lead terminals 42, 43 of the electronic component 41 are inserted to the through-holes 45, 46 of the printed circuit board 44, the lead terminals 42, 43 have ends protruding from the through-holes 45, 46. Then, the ends of the lead terminals 42, 43, protruding from the through-holes 45, 46, are dipped in the DIP flow 47 to allow the electronic component 41 to be mounted on the printed circuit board 44 by soldering. However, during such soldering step, the solder is often formed in inadequate statuses as shown in FIG. 4B and the through-holes are liable to be insufficiently filled with solder. Moreover, the through-holes 45, 46 have surfaces formed with lands 48, 49, respectively.

FIGS. 5A to 5C are views showing a process in which an electronic component 57 is mounted on a printed circuit board 54 using solder pastes 52, 53.

The solder pastes 52, 53 are solder pastes for use in the mounting of SMD (Surface Mount Device).

When mounting the SMD, masking treatment is conducted to print solder paste 52, 53 on the printed circuit board 54 in areas where the SMD is mounted. When this takes place, solder pastes are also printed on through-holes 55, 56.

FIG. 5A is a view showing the solder pastes 52, 53 being printed on the through-holes, respectively. As shown in FIG. 5B, lead terminals 58, 59 of an electronic component 57 are inserted to the through-holes 55, 56, respectively. Due to the presence of the solder pastes 52, 53 printed on the through-holes 55, 56, no need arises for solder rings to be provided on the lead terminals 58, 59. As shown in FIG. 5C, further, reflow treatment is conducted to cause the solder pastes 52, 53 to melt and the electronic component 57 is soldered to and mounted on the printed circuit board 54.

With such technology, the SMD can be mounted and the lead terminals 58, 59 of the electronic component 57 are inserted to the through-holes 54, 55, respectively, to allow the electronic component 57 to be mounted. Thus, the electronic component 57 can be efficiently mounted on the printed circuit board 54.

Additionally, under a circumstance where the electronic component is wrongly mounted on the printed circuit board, a need arises for removing the electronic component from the printed circuit board.

FIG. 16 is a view showing how an electronic component is taken out of a printed circuit board.

Under a circumstance where the electronic component 1602 is wrongly mounted on the printed circuit board 1605, the electronic component 1602 is removed from the printed circuit board 1605 using a nipper.

To remove the electronic component 1602 from the printed circuit board 1605, the heating is carried out under a condition where the printed circuit board 1605 is dipped in a DIP flow batch 1606. The printed circuit board 1605 is heated at temperatures for solder to be melted.

After the solder has been melted, lead terminals 1603, 1604 are taken out of through-holes of the printed circuit board 1605 to remove the electronic component 1602 to be removed from the printed circuit board 1605.

However, the related arts described above encounter issues described below.

With mounting technique shown in FIGS. 3A and 3B, the bracket 40 has a surface (herein referred to as a lower surface with which the printed circuit board is held in contact) formed in a flat surface on which the electronic component 31 is not placed. As the solder rings are melted to allow the electronic component 31 to be mounted onto the print circuit board, the lower surface of the bracket 40 is brought into contact with a surface (hereinafter referred to as an upper surface) of the print circuit board and, hence, a difficulty is encountered in forming solder fillets on the upper surface of the printed circuit board.

Therefore, the electronic component 31 becomes hard to be firmly soldered onto the printed circuit board with the resultant difficulty in connecting the electronic component 31 to the printed circuit board with sufficient strength.

Further, with the related art shown in FIGS. 4A and 4B, also, under circumstances like those where a length of the lead terminal is shorter than the thickness of the printed circuit board 44 or where the ends of the lead terminals 42, 43 protruding from the through-holes 45, 46 are shorter than the thickness of the printed circuit board 44, insides of the through-holes 45, 46 are supplied with solders 50, 51 only in inadequate amounts. This results in increased probability of poor connection.

With the related art shown in FIGS. 5A to 5C, the solder pastes 52, 53 are supplied to the through-holes 55, 56 using soldering paste printing and subjected to reflow treatment for soldering. However, when using a printed circuit board with increased thickness, no solder is supplied to the insides of the through-holes 55, 56 to the extent to completely fill the same. Therefore, in a case where the electronic component is mounted on the printed circuit board using soldering paste printing, increased probability takes place for the occurrence of poor connection between adjacent layers. With the amounts of solder pastes used in the SMD mounting, if the printed circuit board has a thickness more than 2 mm, the electronic component becomes hard to be mounted through the use of through-hole connection with adequate strength.

Further, under a circumstance where the electronic component is wrongly mounted onto the printed circuit board, the electronic component is removed from the printed circuit board using the nipper with the resultant increase in a time period for removing the electronic component.

Therefore, during a period in which the electronic component is being removed, solder is continued in melting to cause the printed circuit board to be heated for an excessively long time period and an issue arises with the occurrence of breakdown of the printed circuit board.

### SUMMARY OF THE INVENTION

Accordingly, the present invention provides a mounting material alignment substrate, a mounting device, a mounting method and a circuit substrate manufacturing method that make it possible to reliably remove an electronic component, mounted on a printed circuit board using through-holes, in the shortest time period.

One aspect of the present invention provides a mounting material alignment plate used to place an electronic component to be mounted on a circuit substrate and having a plurality of bores through which terminals of the electronic component to be placed can be passed. The mounting material alignment plate comprises dent portions formed on one surface, on which the electronic component is placed, around the individual bores, and recess portions formed on another surface opposite to the one surface on which the electronic component is placed.

According to the present invention, the electronic component, mounted on the printed circuit board using the bracket, can be reliably taken out of the printed circuit board in an efficient fashion. This makes it possible to avoid damage to the printed circuit board due to a heating time period and efficiently reutilize the printed circuit board and the electronic component.

### BRIEF DESCRIPTION OF THE DRAWINGS

FIGS. 1A to 1C are conceptual diagrams showing one mounting technology of the related art.

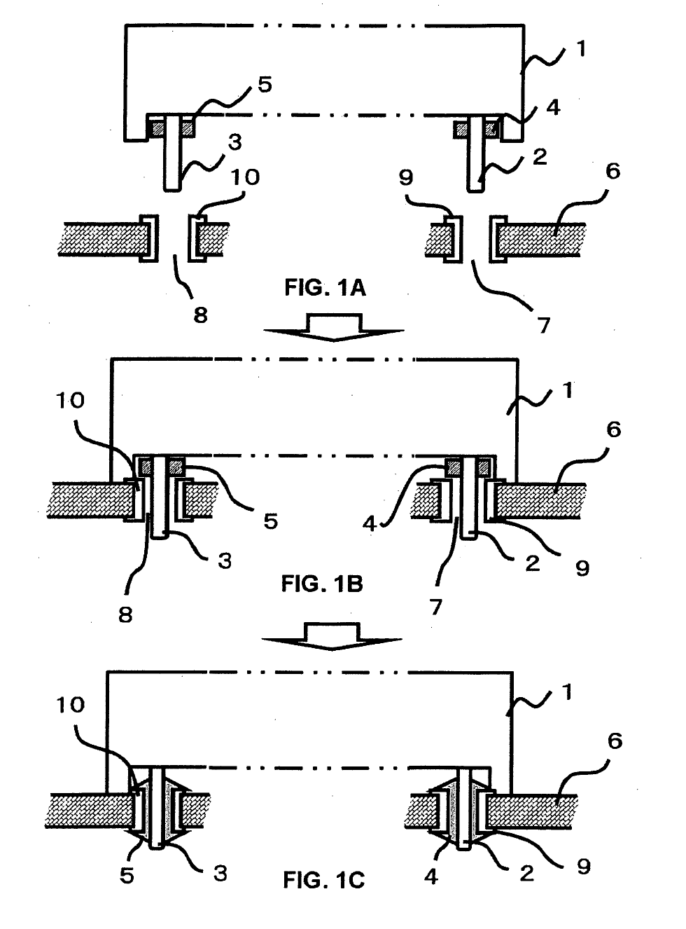

FIG. 2 is a conceptual diagram of another mounting technology of the related art.

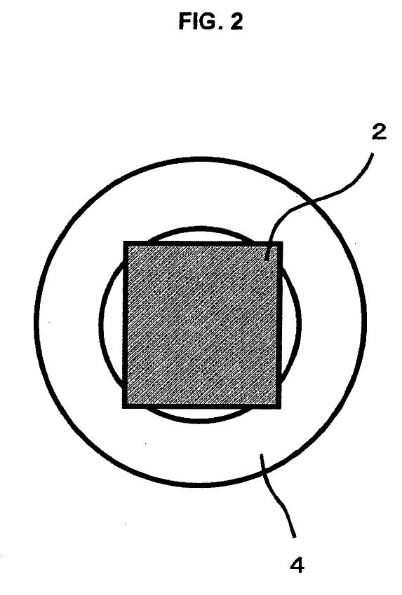

FIGS. 3A and 3B are conceptual diagrams showing another mounting technology of the related art.

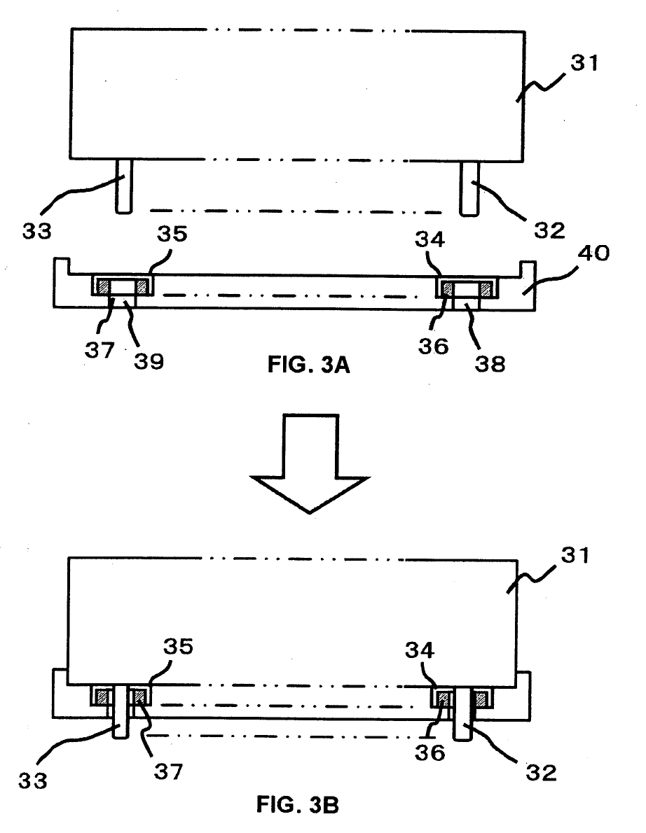

FIGS. 4A and 4B are conceptual diagrams showing another mounting technology of the related art.

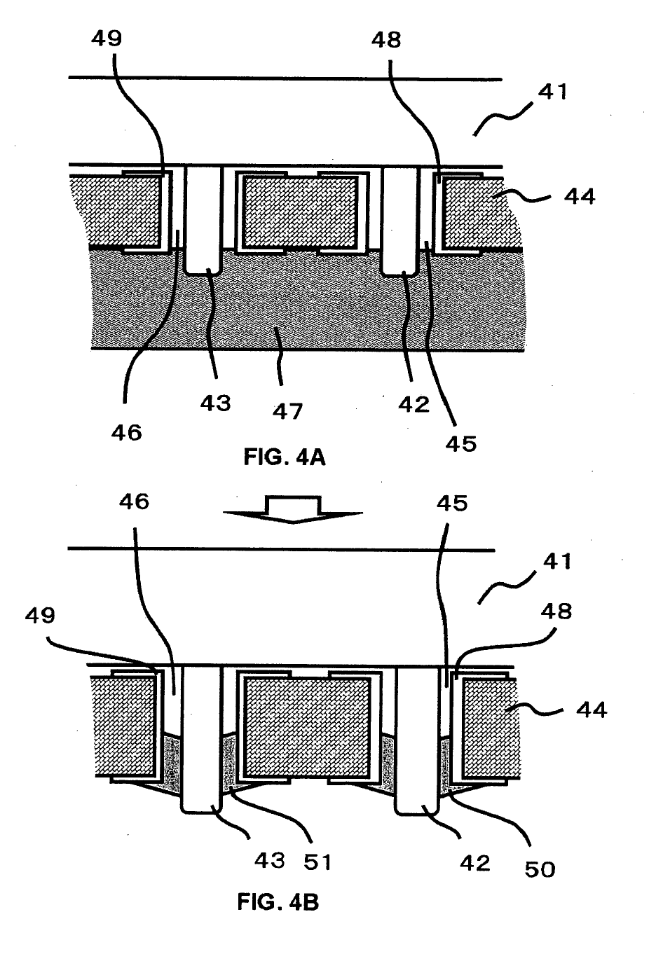

FIGS. 5A to 5C are conceptual diagrams showing another mounting technology of the related art.

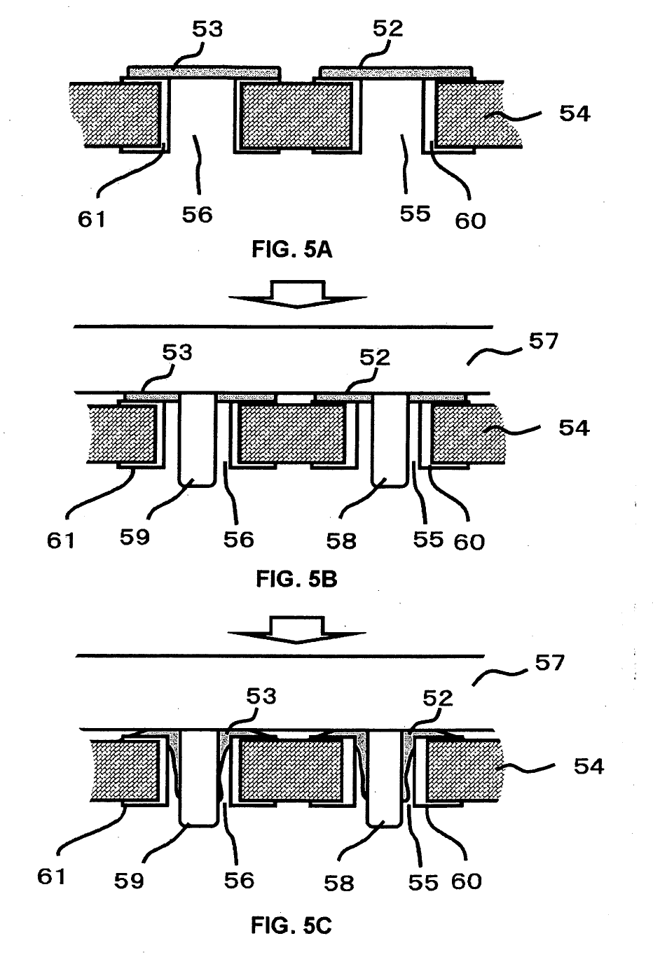

FIG. 6 is a cross-sectional view of a bracket of an embodiment according to the present invention.

FIGS. 7A to 7C are external views of the bracket shown in FIG. 6 according to an embodiment of the present invention.

FIG. 8 is a view showing the bracket to which lead terminals are inserted according to an embodiment of the present invention.

FIGS. 9A and 9B are views showing a dent and a counterbore of the bracket shown in FIG. 6 according to an embodiment of the present invention.

FIGS. 10A to 10D are views showing a sequence of mounting an electronic component on a printed circuit board of the present embodiment according to an embodiment of the present invention.

FIG. 11 is an enlarged view showing a status in which a through-hole is filled with solder according to an embodiment of the present invention.

FIGS. 12A to 12C are views showing a sequence of removing electronic component from the printed circuit board according to an embodiment of the present invention.

FIG. 13 is a block diagram of hardware of a mounting device according to an embodiment of the present invention.

FIG. 14 is a view showing lead terminals inserted to the bracket according to an embodiment of the present invention.

FIGS. 15A and 15B are views showing a dent and a counterbore of a bracket according to an embodiment of the present invention.

FIG. 16 is a view showing how an electronic component is taken out of a printed circuit board.

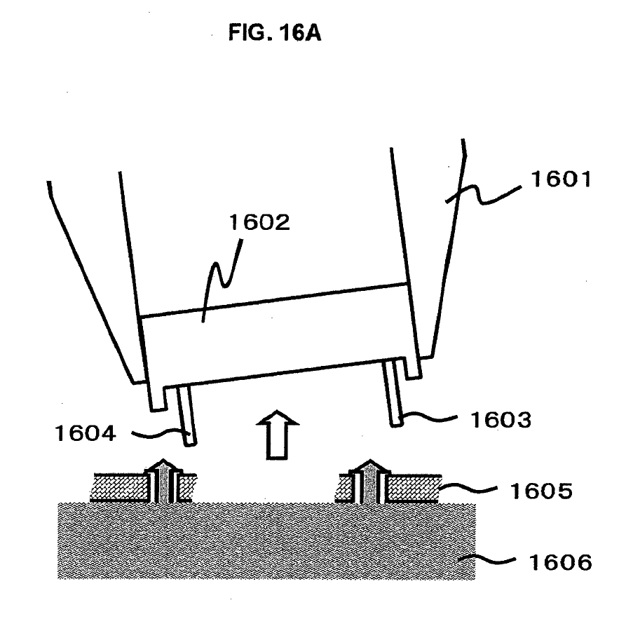

### DESCRIPTION OF THE PREFERRED EMBODIMENTS

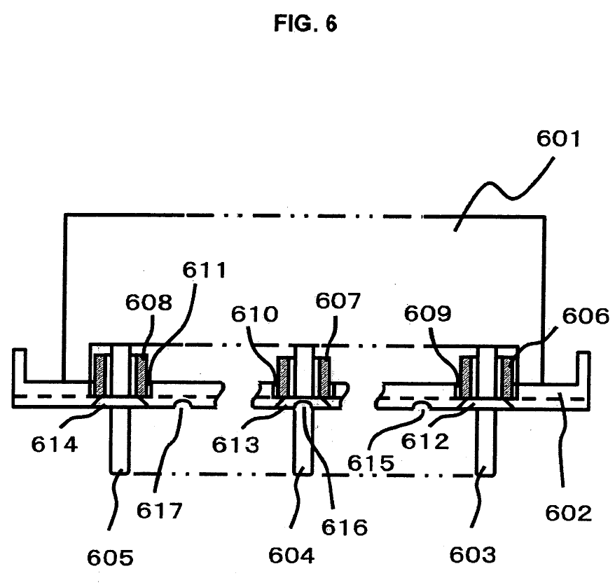

FIG. 6 is a cross-sectional view of a bracket of an embodiment according to the present invention.

With the present embodiment, the terminology “bracket” referred to a member used for mounting an electronic component on a printed circuit board and serves to locate solders onto the printed circuit board at areas in alignment with through-holes.

The electronic component 601 is placed on the bracket 602. Here, a surface of the bracket on which the electronic component 601 is positioned is referred to as an upper surface.

Further, the electronic component 601 has lead terminals 603, 604, 605. The lead terminals 603, 604, 605 are inserted to the through-holes of the printed circuit board and soldered thereto such that the electronic component 601 is mounted onto the printed circuit board.

The upper surface of the bracket 602 is formed with dents 609, 610, 611 for placing solder rings 606, 607, 608 therein, respectively. With the present embodiment, the dents referred to as the “counterbores” mean indentations formed in the bracket 602 for placing the solder rings.

The bracket 602 has the other surface, opposite to the upper surface, which is also formed with dents 612, 613, 614. Here, the other surface of the bracket 602 opposite to the upper surface is referred to as a lower surface.

The dents 612, 613, 614 are formed in the bracket 602 at areas beneath the counterbores 609, 610, 611, respectively. The dents 612, 613, 614 and the counterbores 609, 610, 611 are connected to each other and the bracket 602 is formed with bores. With the present embodiment, the bores are circular in configuration.

When the solder rings 606, 607, 608 are placed in the counterbores 609, 610, 611, respectively, the lead terminals 603, 604, 605 penetrate through the bracket 602 passing across the bores of the solder rings 606, 607, 608 and the bores formed in the bracket 602 for placement the solder rings 606, 607, 608 on the bracket 602.

The dents 612, 613, 614 are formed in tapered shapes, respectively, each extending toward the lower surface with a center aligned with a center of each bore formed in the bracket 602.

In FIG. 6, the electronic component 601 and the bracket 602 are shown in shortened states and the lead terminals 603, 604, 605, the solder rings 606, 607, 608, the counterbores 609, 610, 611 and the dents 612, 613, 614 are shown in three pieces, respectively.

Further, the lower surface of the bracket 602 is formed with recesses 615, 616, 617. Centers of recesses 615, 616, 617 are the centers of counterbores 609, 610, 611, respectively.

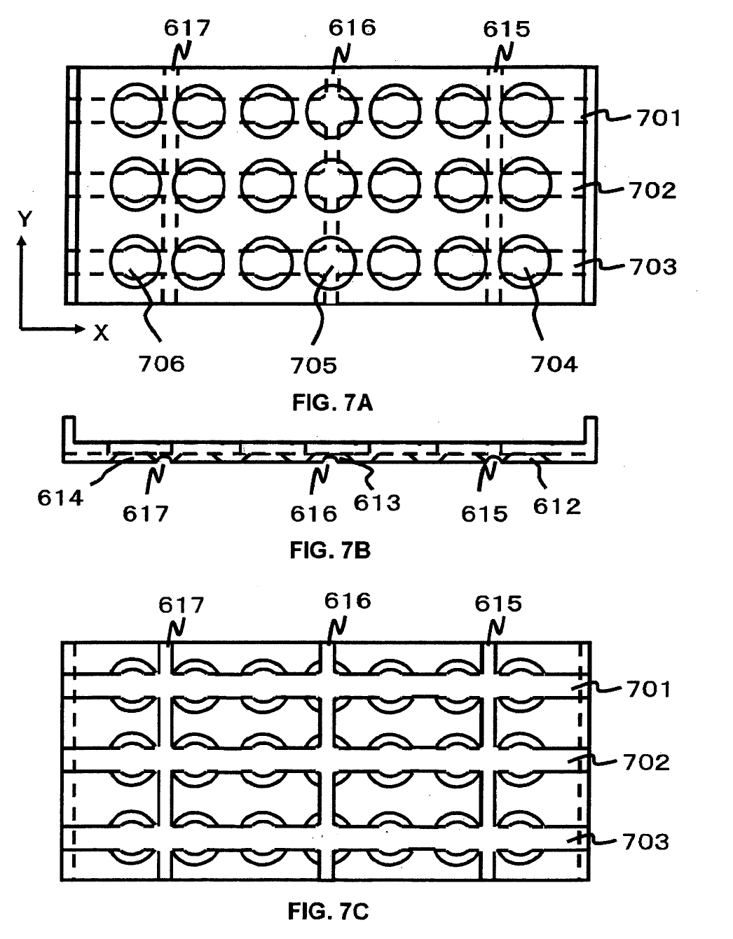

FIGS. 7A to 7C are external views of the bracket 602 according to an embodiment of the present invention.

FIG. 7A is a view showing the bracket 602 as viewed from the above. FIG. 7B is a view showing the bracket 602 as viewed from a side thereof. FIG. 7C is a view showing the bracket 602 as viewed from a lower side thereof.

With the present embodiment, the bracket 602 has seven dents arrayed in an X-direction and three dents arrayed in a Y-direction in a reticular pattern with a total sum of twenty-one counterbores. These counterbores are equidistantly spaced in the X- and Y-directions, respectively.

Likewise, the lower surface of the bracket 602 has seven dents arrayed in the X-direction and three dents arrayed in the Y-direction in a reticular pattern with a total sum of twenty-one counterbores. These dents are equidistantly spaced in the X- and Y-directions, respectively, such that the counterbores and the dents are formed in the same positions with respect to X- and Y-coordinates on both the upper and lower surfaces.

Here, the counterbores and the dents will be described below with reference to typical examples of the counterbores 609, 610, 611 and the dents 612, 613, 614. This layout corresponds to a layout of the counterbores and the dents shown in FIG. 6.

The counterbores and the dents are formed on the upper and lower surfaces in circular shapes, respectively. The expression of “the same position in the X- and Y-coordinate” means that centers of the respective circles are identical. Thus, radii of the counterbores and the dents are formed in the same length.

The counterbores 609, 610, 611 are graved in the bracket 602 in column configurations, respectively. The dents 612, 613, 614 are formed in respective tapered shapes toward the lower surface of the bracket.

With the present embodiment, the term “tapered shape” means that the dents 612, 613, 614 are formed in conical shapes that are flared toward the lower surface of the bracket 602 at the centers of the bores passing through the counterbores 609, 610, 611 and the dents 612, 613, 614, respectively.

The lower surface of the bracket 602 is formed with the recesses 615, 616, 617, 701, 702, 703. The recesses 615, 616, 617 are linearly arrayed in parallel to the Y-direction and the recesses 701, 702, 703 are linearly arrayed in parallel to the X-direction.

The recess 616 is formed at a center of the bracket 602 in the X-direction and extends in the Y-direction and the recesses 615, 617 are formed at positions equidistantly spaced from the recess 616 in the X-direction and extend in parallel to the Y-direction.

The recess 702 is formed at a center of the bracket 602 in the Y-direction and extends in the X-direction. The recesses 701, 703 are formed at positions equidistantly spaced from the recess 702 in the Y-direction and extend in parallel to the X-direction.

FIG. 7A shows the recesses 615, 616, 617, 701, 702, 703 in dotted lines, respectively, which are invisible from the upper surface of the bracket 602 and designated in a status formed on the lower surface of the bracket 602. That is, the recesses 615, 616, 617, 701, 702, 703 have depths less than the thickness of the bracket 602. Here, the recesses 615, 616, 617, 701, 702, 703 are formed in uniform width and depth. Here, the expression “the recesses 615, 616, 617, 701, 702, 703 are formed in uniform width and depth” means that the recesses 615, 616, 617, 701, 702, 703 are formed in the bracket 602 with a fixed width and depth. That is, this is meant by the fact, as shown in FIGS. 7A to 7C, that the recesses 615, 616, 617, 701, 702, 703 are linearly formed with no difference in width and no difference in depth at both ends of the bracket 602.

Further, the recesses 615, 616, 617, 701, 702, 703 have the same depth. Additionally, the recesses 615, 616, 617, 701, 702, 703 have the same depths as those of the dents 612, 613, 614. Of course, it doesn't matter if the recesses 615, 616, 617, 701, 702, 703 and the dents 612, 613, 614 have depths different from each other. With the present embodiment, the recesses 701, 702, 703 are set to have larger widths than those of the recesses 615, 616, 617. Also, the counterbores and the associated dents are connected to each other by means of bores 704, 705, 706. The bores 704, 705, 706 are formed at centers of the counterbores and the dents, respectively, in circular shapes smaller in diameter than those of the counterbores and the dents.

The bores 704, 705, 706 are configured to have larger sizes than those of the lead terminals of the electronic component to enable the insertion of the lead terminals. Here, no limitation is intended to particular shapes of the lead terminals and the lead terminals may take any shape or size provided that the lead terminals can be inserted to the bores 704, 705, 706.

The present embodiment takes the form of a structure wherein a single electronic component is placed on the bracket 602 to allow the lead terminals to be inserted to all of the counterbores and the dents.

Further, the bracket 602 has both ends spaced in the X-direction and formed with walls 707, 708, respectively, which are greater in height than the thickness of the bracket 602. These walls 707, 708 serve to prevent the solder rings from falling out of the bracket 602 during placements of the solder rings. Therefore, it doesn't matter if the bracket 602 is structured to have both ends spaced in the Y-direction and formed with walls that are greater in height than the thickness of the bracket 602.

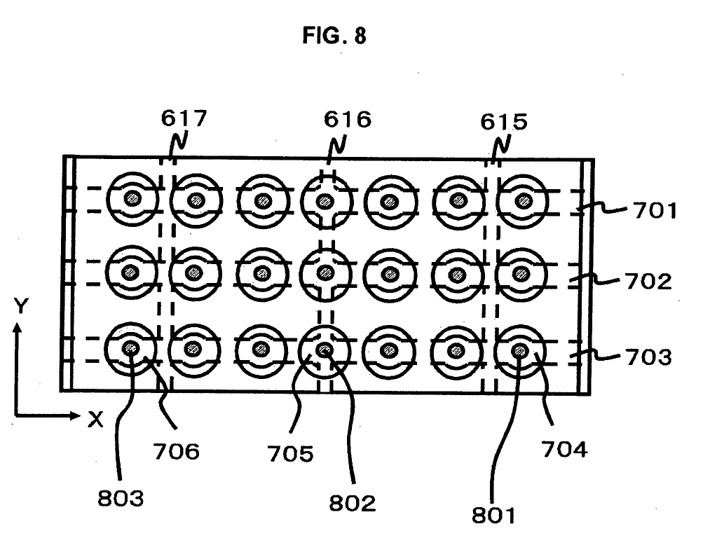

FIG. 8 is a view in which the lead terminals are inserted to the bracket according to an embodiment of the present invention.

FIG. 8 is a view showing the bracket, as viewed from an upper side thereof with no illustration of a body of the electronic component, which represents a status wherein a lead terminal 801 is inserted to the bore 704.

Lead terminals 801, 802, 803 are inserted to the bores 704, 705, 706 of the counterbores 609, 610, 611, respectively, one by one. The other lead terminals are similarly inserted to the other counterbores, respectively, one by one. Here, the lead terminals have cross-sectional shapes each formed in a circular configuration.

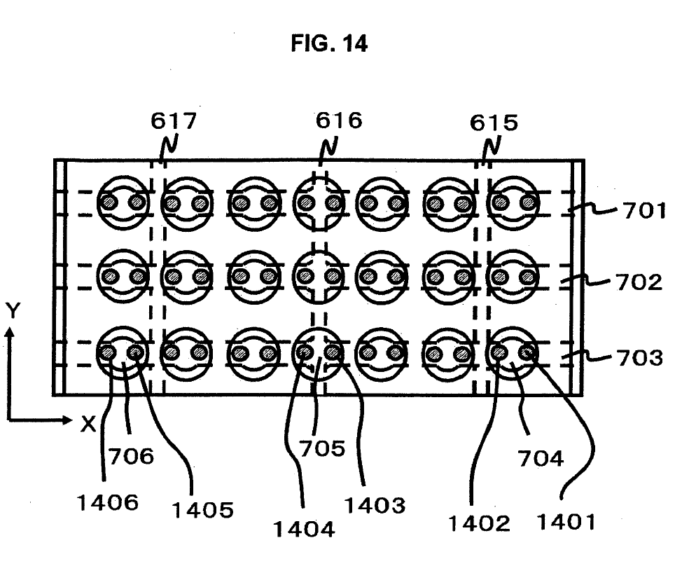

In an alternative, as shown in FIG. 14, a bracket may take the form of a structure wherein lead terminals 1401, 1402, 1403, 1404, 1405, 1406 are inserted to the bores 704, 705, 706 of the counterbores 609, 610, 611 two by two. In such an alternative, the bores of the other counterbores accommodates associated lead terminals two by two.

In FIG. 8, solder rings, to be placed in the counterbores 609, 610, 611, are omitted and not illustrated.

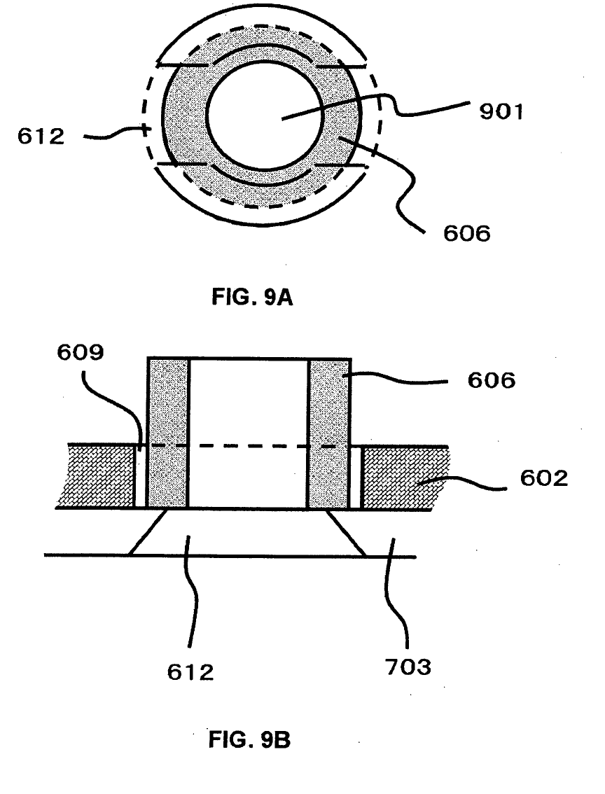

FIGS. 9A and 9B are views showing the counterbore and the dent according to an embodiment of the present invention.

FIG. 9A is a view showing the dent as viewed from a lower side of the bracket. FIG. 9B is a cross-sectional view showing the counterbore, the dent and the solder ring as viewed from a lateral side of the bracket. The cross-sectional view of FIG. 9B is taken on line parallel to the X-direction intersecting centers of the counterbore 609 and the dent 612.

The dent 612 and the recess 703 are formed in the same depth and the recess 703 is formed in a shape to across the bore 704.

The solder ring 606 has a bore (inner diameter) 901 that is smaller in diameter than the bore 704. Further, the solder ring has an outer diameter smaller in diameter than the dent 612 and further smaller in diameter than the counterbore 609.

The lead terminal extending from the electronic component is formed in a size to pass through the bore 901. Also, a through-hole formed in the printed circuit board is less in size than the bore 901 to allow the lead terminal to be inserted to the through-bore while permitting melted solder to be filled.

As shown in FIG. 9B, the dent 612 is formed in the tapered shape flaring toward the lower surface of the bracket 602 at the center of the bore 704 that is larger in diameter than that of the bore 901. Although FIG. 9B designates an outline of the dent 612 in a solid line with a view to representing the dent 612, such a line is not actually present.

In FIG. 9A, further, although a broken line, for representing a shape of the dent 612, is not present because the recess 703 actually extends across the dent 612, such a broken line is designated for an assist of representing the shape of the dent 612. A contour of the solder ring 606 is partly designated in broken line, which represents an area invisible as viewed from the lower side of the bracket 602, and shown as an assist for illustrating the solder ring 606.

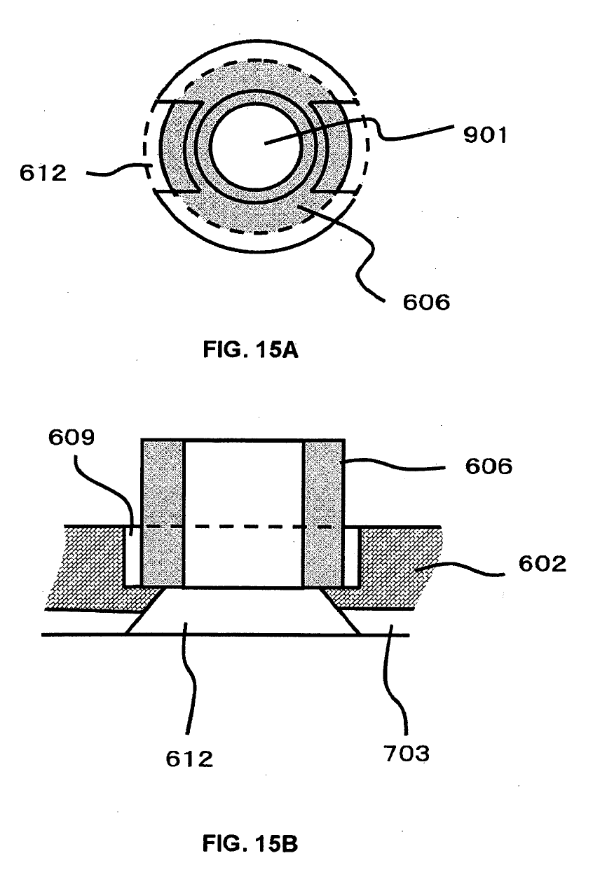

FIGS. 15A and 15B are views showing a counterbore and a dent of a bracket of a modified form of the present embodiment.

FIG. 15A is a view showing the dent as viewed from a lower side of the bracket 602A. FIG. 15B is a cross-sectional view showing the counterbore, the dent and the solder ring as viewed from a lateral side of the bracket 602. The cross-sectional view of FIG. 15B is taken on line parallel to the X-direction intersecting centers of the counterbore 609 and the dent 612.

The dent 612 has a depth greater than that of the recess 703 in structure wherein the recess 703 does not extend across the bore 704.

The solder ring 606 has a bore (inner diameter) 901 that is smaller in diameter than the bore 704. Further, the solder ring 606 has the outer diameter smaller in diameter than the dent 612 and further smaller in diameter than the counterbore 609.

The lead terminal extending from the electronic component is formed in a size to pass through the bore 901. Also, the printed circuit board has the through-hole, less in diameter than the bore 901, to allow the lead terminal to be inserted to the through-bore while permitting melted solder to be filled.

As shown in FIG. 15B, the dent 612 is formed in the tapered shape flaring toward the lower surface of the bracket 602 at the center of the bore 704 that is larger in diameter than that of the bore 901. Although FIG. 15B designates the outline of the dent 612 in the solid line with a view to representing the dent 612, such a line is not actually present. In FIG. 15A, further, although a broken line, for representing a shape of the dent 612, is not present because the recess 703A actually extends across the dent 612, such a portion is designated for an assist of representing the shape of the dent 612. A contour of the solder ring 606 is partly designated in broken line, which represents the area invisible as viewed from the lower side of the bracket 602A, and shown as an assist for illustrating the solder ring 606.

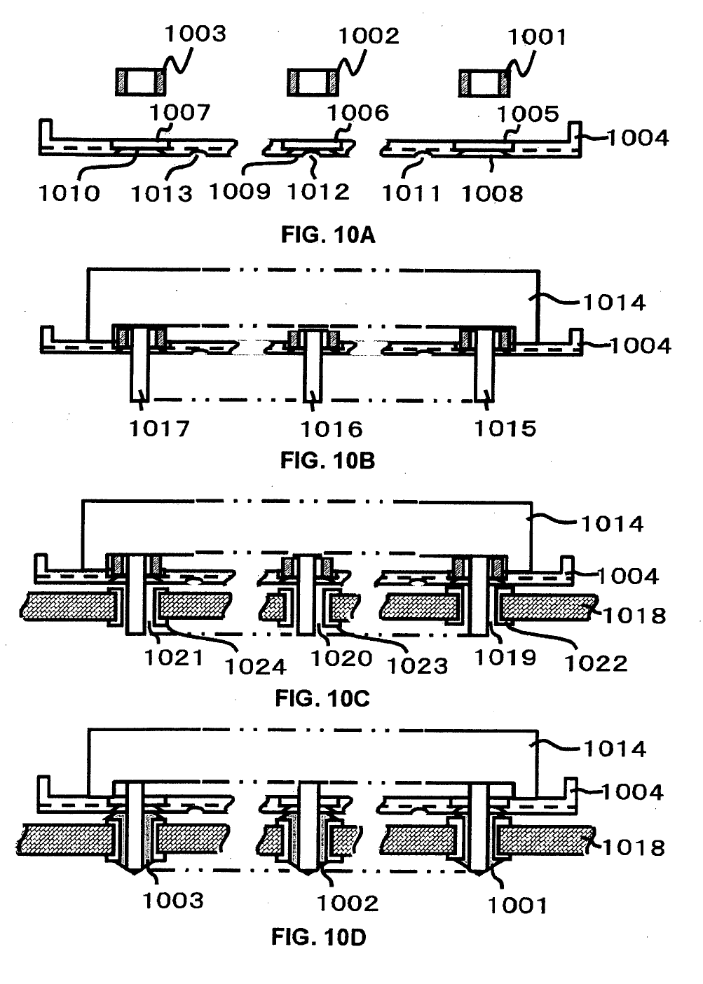

FIGS. 10A to 10D are views showing a process in which an electronic component is mounted on the printed circuit board according to an embodiment of the present invention.

FIG. 10A is a view showing a status before solder rings 1001, 1002, 1003 are placed into counterbores 1005, 1006, 1007 formed in a bracket 1004. The solder rings 1001, 1002, 1003 are then disposed in the counterbores 1005, 1006, 1007, respectively.

The bracket 1004 has a lower surface formed with dents 1008, 1009, 1010. Further, the lower surface of the bracket 1004 is formed with recesses 1011, 1012, 1013.

FIG. 10B is a view in which the electronic component 1014 is mounted on the bracket 1004. The electronic component 1014 has lead terminals 1015, 1016, 1017. The lead terminals 1015, 1016, 1017 are inserted to the counterbores 1005, 1006, 1007 in which the solder rings 1001, 1002, 1003 are disposed, respectively. The counterbores 1005, 1006, 1007 and the dents 1008, 1009, 1010 are connected to each other to be contiguous and the lead terminals 1015, 1016, 1017 have lengths greater than the thickness of the bracket 1004. Therefore, the lead terminals 1015, 1016, 1017 protrude from the lower surface of the bracket 1004. Protruding lengths of the lead terminals 1015, 1016, 1017 are equal in size. Also, it doesn't matter if the lead terminals 1015, 1016, 1017 are different from each other.

FIG. 10C is a view showing a status wherein the bracket 1004 is mounted on a printed circuit board 1018. Protruding ends of the lead terminals 1015, 1016, 1017 are inserted to through-holes 1019, 1020, 1021 formed in the printed circuit board 1018, respectively. The printed circuit board 1018 has the lower surface formed with lands 1022, 1023, 1024 in areas around the through-holes 1019, 1020, 1021, respectively. The lands 1022, 1023, 1024 are formed of copper. With the present embodiment, the lead terminals 1015, 1016, 1017 are inserted to the through-holes 1019, 1020, 1021 and have end portions protruding from the printed circuit board 1018 in structure.

FIG. 10D is a view in which the printed circuit board 1018, on which the bracket 1004 is mounted, is subjected to a reflow process. During the reflow process, the solder rings 1001, 1002, 1003 are caused to melt and filled in the through-holes 1019, 1020, 1021. When this takes place, an upper surface (on which the bracket 1004 is mounted) of the printed circuit board 1018 is formed with fillets. This is because the lower surface of the bracket 1004 is formed with the dents 1008, 1009, 1010 and melted solder is filled in the dents 1008, 1009, 1010.

With such a process, the electronic component 1014 is firmly mounted onto the printed circuit board 1018 with adequate strength. Moreover, since the solder rings 1001, 1002, 1003 are preliminarily placed on the bracket 1004 to allow the solder rings 1001, 1002, 1003 to be located in the areas formed with the through-holes to which the lead terminals 1015, 1016, 1017 are inserted, the electronic component 1014 can be mounted on the printed circuit board 1018 in an efficient fashion.

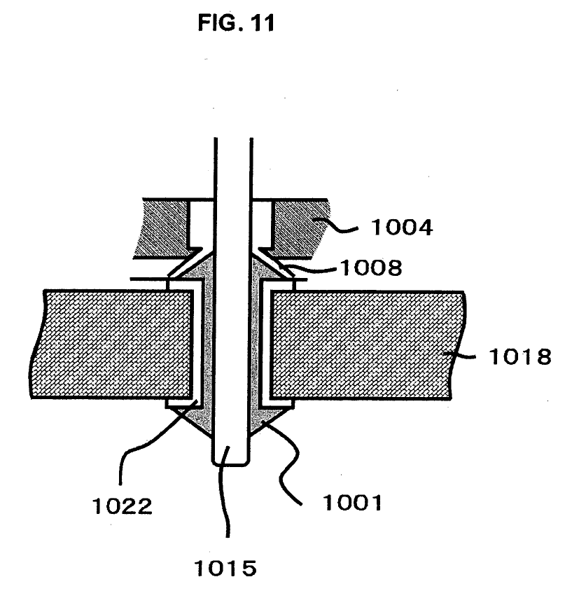

FIG. 11 is an enlarged view showing solder being filled in the through-hole according to an embodiment of the present invention.

Solder 1001 is filled in the through-hole 1019 to fixedly hold the lead terminal 1015 in the through-hole 1019 to be conductive with the printed circuit board 1018. Due to a structure in which a land 1022, formed at an end of the through-hole 1019, is formed of copper, electric conductance can be achieved with high conductivity. Moreover, the lower surface of the bracket 1004 is formed with the dent 1008 in the tapered shape. This allows solder 1001 to be filled in the dent 1008 and, thus, the fillet is formed on the upper surface of the printed circuit board 1018. Since no obstacle for blocking the formation of the fillet is placed on the lower surface of the printed circuit board 1018, the fillet can be also formed on the lower surface of the printed circuit board 1018.

With the present embodiment, although the bracket 1004 is placed in nearly contact with the printed circuit board 1018, the presence of the dent 1008 also enables the fillet to be formed on the upper surface of the printed circuit board 1018.

This results in capability of adequately supplying solder to the through-hole of the printed circuit board 1018 and enables the formation of the fillet on the upper surface of the printed circuit board 1018. Thus, an electronic component can be firmly mounted on a printed circuit board of an increased thickness with adequate strength.

Here, the adequate amount of solder to be supplied can be adjusted depending on a height of a solder ring. With the present embodiment, the solder ring has a height greater than a depth of the counterbore.

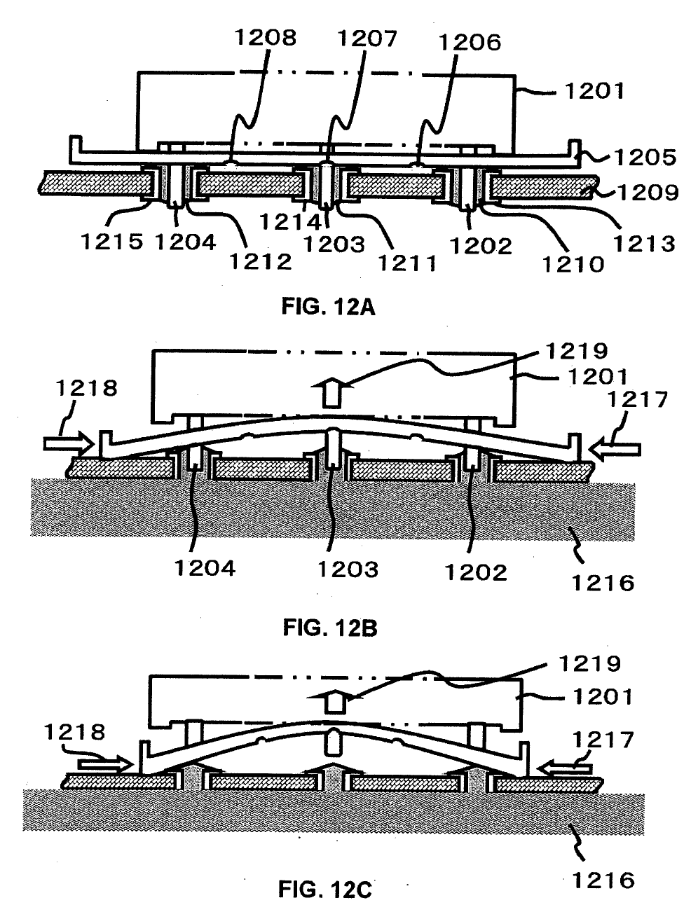

FIGS. 12A to 12C are views showing how the electronic component is removed from the printed circuit board according to an embodiment of the present invention.

FIG. 12A is a view wherein the electronic component 1201 is mounted on the printed circuit board 1209 using a bracket 1205.

The electronic component 1201 has lead terminals 1202, 1203, 1204. The lead terminals 1202, 1203, 1204 are inserted to through-holes formed in the printed circuit board 1209 and held in fixed places by solders 1210, 1211, 1212. Also, the printed circuit board 1209 has a lower surface formed with lands 1213, 1214, 1215 at areas around the through-holes, respectively.

Further, the bracket 1205 has a lower surface (on a side facing the printed circuit board 1209) formed with recesses 1206, 1207, 1208.

FIG. 12B is a view showing the bracket 1205 to which a pressure is applied.

In order to remove the electronic component 1201 from the printed circuit board 1209, the printed circuit board 1209 is heated up until the solders 1210, 1211, 1212 are melted. When this takes place, a DIP flow layer 1216 is located below the printed circuit board 1209.

Pressures 1217, 1218 are applied to both sides of the bracket 1205. Since the bracket 1205 is formed with the recesses 1206, 1207, 1208, the bracket 1205 is easily bowed and the electronic component 1201 can be moved in a direction as shown by an arrow 1219. When this takes place, the solders 1210, 1211, 1212 are caused to melt due to the heating. Therefore, the lead terminals 1202, 1203, 1204 are also caused to move in the direction as shown by the arrow 1219. The pressure 1217 acts in a direction perpendicular to the recesses 1206, 1207, 1208 and also perpendicular to the lead terminals 1202, 1203, 1204. With the present embodiment, the lead terminals 1202, 1203, 1204 are inserted to the through-holes in a direction perpendicular to the bracket 1205 and the printed circuit board 1209.

FIG. 12C is a view showing the bracket 1205 being applied with the pressure.

As shown in FIG. 12C, continuously applying pressures 1217, 1218 further to the bracket 1205 allows the bracket 1205 to further bow and the electronic component 1201 is caused to lift in a further extent in the direction 1219. As a result, the lead terminals 1202, 1203, 1204 get out of the through-holes to enable the electronic component 1201 to be taken off from the printed circuit board 1209. Means for taking the electronic component 1201 from the bracket 1205 on a final stage is composed of a hardware structure for the removal of the electronic component 1201.

Thus, by forming the recesses 1206, 1207, 1208 on the lower surface of the bracket 1205, the electronic component 1201 can be easily taken off from the printed circuit board 1209.

Further, since a time interval, needed for continuous heating to continue the melting of the solders, is shortened, the electronic component can be removed from the printed circuit board without causing damage to the electronic component or the like due to overheating. Therefore, the electronic component or the like can be reutilized.

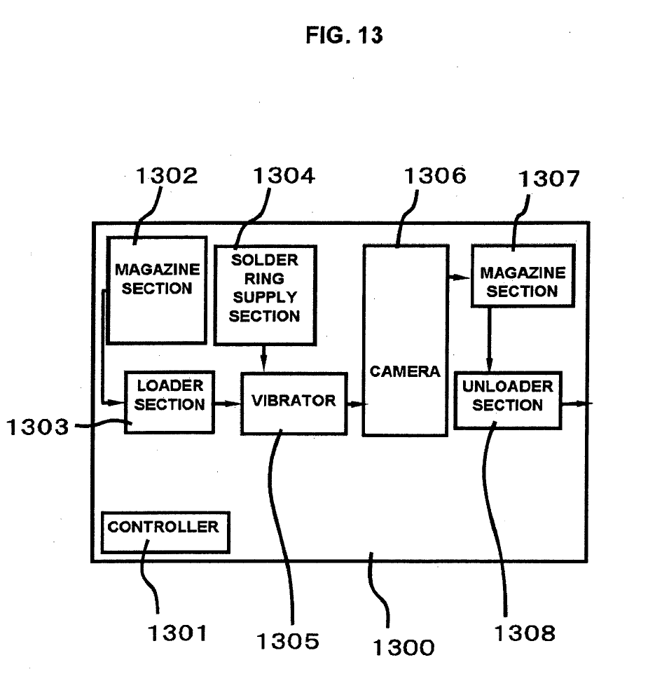

FIG. 13 is a hardware block diagram of a mounting device of the present embodiment according to an embodiment of the present invention.

The mounting device 1300 for mounting an electronic component on a bracket is comprised of a controller 1301, a magazine section 1302, a loader section 1303, a solder ring supply section 1304, a vibrator 1305, a camera 1306, a magazine section 1307 and an unloader section 1308.

The controller 1301 serves to control the operations of the magazine section 1302, the loader section 1303, the solder ring supply section 1304, the vibrator 1305, the camera 1306, the magazine section 1307 and the unloader section 1308.

First, the magazine section 1302 stores therein trays in respective layers in each of which a plurality of brackets are located. With the present embodiment, although no external view for the trays is designated, it is a general practice for the brackets to be placed such that the brackets are placed on the tray in a reticular pattern. Of course, it doesn't matter if the way in which the brackets are placed on that tray is not based on the reticular pattern. For instance, brackets may be placed on the tray in a reticular pattern with a plurality of lines and a plurality of rows.

The loader section 1303 selects a single tray from the magazine section 1302 and takes the tray out of the magazine section 1302. The tray is selected in such a way that one tray on the uppermost layer is selected from among the trays stored in the magazine section 1302. Of course, the way of selecting the tray is not limited to such a concept.

The loader section 1303 allows the solder ring supply section 1304 to supply solder rings to the pullout tray. The solder ring supply section 1304 allows the number of solder rings to be scattered onto the tray, on which a plurality of brackets are placed, for supply to the counterbores by a value equivalent to a sum of the counterbores formed in all of brackets. Then, the vibrator 1306 causes the trays to horizontally vibrate to locate the solder rings into the counterbores.

The camera 1306 serves to check whether the solder rings are located in the counterbores. If the solder rings are not correctly located in the relevant counterbores, using the vibrator 1305 allows the solder rings to be correctly located. It doesn't matter if a maintenance stuff corrects the placements of the solder rings by his hand.

The electronic component locating section 1307 stores electronic components to be mounted onto the printed circuit board. The electronic component locating section 1307 allows the electronic component to be located on the bracket whose counterbores are supplied with the solder rings. When locating the electronic component, the bracket is placed on the tray.

The unloader section 1308 stores the tray in a magazine section different from the magazine section 1302. Of course, it doesn't matter if the magazine section for the unloader section 1308 to store the tray includes the magazine section 1302.

The tray stored in the magazine section is taken out again. The bracket is taken out of the tray and the bracket is located on the printed circuit board for the electronic component to be mounted. Then, the printed circuit board is subjected to a reflow process. Although no hardware structure for executing the reflow process is illustrated in the mounting device shown in FIG. 13, it doesn't matter if the mounting device has the hardware structure for executing the reflow process.

Further, although no pressing means is illustrated in FIG. 13, the mounting device shown in FIG. 13 may include the pressing means for applying the pressures 1217, 1218 shown in FIGS. 12A to 12C. The pressing operation of electronic component removing means corresponds to the pressings to be executed by the pressing means. Also, during overheating operation for mount material of the electronic component removing means, the overheating operation is executed using a hardware structure for performing a reflow process.

Additionally, the mounting device 1300 may have a hardware structure for taking out the electronic component 1201 out of the raised bracket 1205. No hardware structure for taking out the electronic component 1201 is illustrated FIG. 13.

During the reflow process, the heating is executed to a temperature for the solder rings to be melted. Further, after the through-holes, formed in the printed circuit board, has been filled with solder, the printed circuit board is cooled again for solidifying solder to allow the electronic component to be mounted on the printed circuit board.

With the present embodiment, a mounting material alignment plate is comprised of the bracket and mounting material is comprised of solder. Solder includes lead-free solder. A first dent corresponds to the counterbore and a second dent corresponds to the dent of the present embodiment.

While the solder ring supply section 1303 scatters the number of solder rings onto the tray, on which a plurality of brackets are placed, for supply to the counterbores by a value equivalent to a sum of the counterbores formed in all of the brackets, the present invention is not limited to such a structure and it doesn't matter if the present invention takes a structure adapted to supply the greater number of solder rings than the number of a sum of the counterbores.

Further, with the present embodiment, terminals represent the lead terminals. A circuit substrate corresponds to the printed circuit board and terminal connector portions correspond to the counterbores. A mounting material locating means includes a means to be realized by the solder ring supply section and the vibrator. A terminal inserting means represents a means to be realized by the electronic component locating section. Although the mounting device shown in FIG. 13 has no hardware corresponding to a reflowing means, with the structure shown in FIG. 13, the bracket on which the electronic component is mounted is subjected to a reflow process by a device for executing the reflow process.

With the present embodiment, the bracket is formed with the counterbores and the dents each by the number of twenty one but the present invention is not limited to such a numeric value and it doesn't matter if another numeric value is employed.

While the counterbores and the dents are formed on the upper and lower surfaces of the bracket in circular shapes, respectively, the present invention is not limited to such shapes and it doesn't matter if another shape is employed. Moreover, it doesn't matter if the counterbores and the dents do not have same diameter. In addition, although the counterbores and the dents have the same center positions, the present invention is not limited to such a concept and it doesn't matter if the respective circles have deviated centers. Also, it doesn't matter if one of the counterbore and the dent has a circular shape and the other one has, for instance, a rectangular shape.

While the counterbores and the dents are formed in the equidistantly spaced positions both in the X- and Y-directions, the present invention is not limited to such a layout and no equidistantly spaced layout may be taken.

While the three rows of recesses are formed both in the X- and Y-directions, the present invention is not limited to such a layout and it doesn't matter if the bracket has the other number of rows both in the X- and Y-directions.

While the recesses are linearly formed both in the X- and Y-directions, the present invention is not limited to such a layout and it doesn't matter if the recesses are formed in other configurations.

While the recesses 616, 702 are formed at the central areas of the bracket 602 both in the X- and Y-directions thereof, the present invention is not limited to such a layout and it doesn't matter if the recesses 616, 702 are formed in positions dislocated from the central areas of the bracket 602 in the X- and Y-directions thereof.

While the recesses 615, 616, 617, 701, 702, 703 are formed in uniform width and depth, the present invention is not limited to such a layout and the recesses may not need to have the uniform width and depth.

While the recesses 615, 616, 617, 701, 702, 703 have the same depth, the present invention is not limited to such a concept and it doesn't matter if the recesses are formed in different depths.

While the recesses 701, 702, 703 have larger widths than those of the recesses 615, 616, 617, the present invention is not limited to such a layout and it doesn't matter if the recesses are formed in opposite structures or it doesn't matter if the recesses 615, 616, 617, 701, 702, 703 are formed in the same widths. Furthermore, it doesn't matter if the recesses 615, 616, 617, 701, 702, 703 are formed in different widths, respectively.

Next, here lists modified forms and other technical alternatives or the like of the mounting material alignment plate of the present embodiment according to the present invention set forth above.

(1) While with the present embodiment mentioned above, the electronic component is mounted on the printed circuit board using solder, the present invention is not limited to such a concept and it doesn't matter if such a component is mounted using other material.

(2) While with the present embodiment set forth above, the recesses are formed on the printed circuit board in positions symmetric with respect to the center line of the bracket, the present invention is not limited to such a layout and it doesn't matter if the recesses are formed in other structures.

What is claimed is:

1. A circuit unit comprising:
a plurality of electronic components;
a printed circuit board on which the plurality of electronic components are mounted by using solder chips, formed a plurality of hole portions for inserting terminals of the electronic components; and
an alignment plate formed a plurality of bores, a plurality of first dent portions, and a plurality of recess portions, said dent portions being formed around respective bores on one surface of the alignment plate for receiving said solder chips, said recess portions being formed around the bores respectively on the other surface opposite to said one surface and extending across said alignment plate so as to bend when the alignment plate receives compressing force in a direction perpendicular to the extending direction of the recess, said alignment plate being placed on the printed circuit board so as to enable to insert the terminals of the electronic components in said bores.

2. The circuit unit according to claim 1, wherein the alignment plate is formed in a rectangular shape and the recess portions are formed in parallel to one side of the other surface opposite to the one surface of the alignment plate.

3. The circuit unit according to claim 2, wherein one of the recess portions passes across a center of the other surface of the alignment plate.

4. The circuit unit according to claim 1, wherein one of the recess portions passes across a center of the other surface of the alignment plate, and the other recess portions are formed in areas symmetric to each other with respect to the one of the recess portions passing across the center of the one surface.

5. The circuit unit according to claim 1, wherein a plurality of second dent portions are formed around respective bores on the other surface opposite to said one surface of the alignment plate.
